(19) United States
(12) Patent Application Publication
(10) Pub. No.: US 2026/0190551 A1
(43) Pub. Date: Jul. 2, 2026

(54) Light Emitting Element and Display Apparatus

(71) Applicant: LG Display Co., Ltd., Seoul (KR)

(72) Inventors: Il-Soo Kim, Paju-si (KR); YongSeok Kwak, Paju-si (KR); Myungsoo Han, Paju-si (KR)

(21) Appl. No.: 19/324,579

(22) Filed: Sep. 10, 2025

(30) Foreign Application Priority Data
Dec. 27, 2024 (KR) 10-2024-0198007

(51) Int. Cl. H10H 20/831; H10H 20/01; H10H 20/821; H10H 20/833; H10H 20/84; H10H 20/857

(52) U.S. Cl. CPC H10H 20/8312; H10H 20/821; H10H 20/833; H10H 20/84; H10H 20/857; H10H 20/032

(57) ABSTRACT

Embodiments of the present disclosure relate to a light emitting element and a display apparatus. More particularly, a light emitting element and a display apparatus comprise: a substrate; a first semiconductor layer disposed on the substrate; a light emitting layer disposed on the first semiconductor layer; a second semiconductor layer disposed on the light emitting layer; a first electrode connected to the first semiconductor layer; and a second electrode disposed on and connected to the second semiconductor layer. The first electrode is connected to the first semiconductor layer through a via hole of the second semiconductor layer and the light emitting layer. By maximizing the area of the light emitting layer, a light emitting element and a display apparatus with high luminous efficiency can be provided.

### CROSS REFERENCE TO RELATED APPLICATION

This application claims priority under 35 U.S.C. § 119(a) to the Republic of Korea Patent Application No. 10-2024-0198007, filed on Dec. 27, 2024, the entire contents of which are hereby expressly incorporated by reference into the present application.

### TECHNICAL FIELD

Embodiments of the present disclosure relate to a light emitting element (e.g., light emitting diode) and a display apparatus.

### BACKGROUND

In recent years, the light emission efficiency of light emitting elements (e.g., light emitting diodes) has become increasingly important for display apparatuses that provide higher resolution, image quality, and stability. In a display apparatus, a decrease in light emission efficiency may occur due to non-emitting regions of the light emitting element (e.g., light emitting diode).

### SUMMARY

Exemplary embodiments of the present disclosure may provide a light emitting element (e.g., light emitting diode) and a display apparatus having improved light emission efficiency.

Exemplary embodiments of the present disclosure may provide a light emitting element (e.g., light emitting diode) and a display apparatus capable of achieving high resolution by maximizing the area of the light emitting layer.

According to an exemplary embodiment of the present disclosure, a display apparatus includes a substrate and a light emitting element disposed on the substrate. The light emitting diode element includes a first semiconductor layer, a light emitting layer disposed on the first semiconductor layer, a second semiconductor layer disposed on the light emitting layer, a first electrode connected to the first semiconductor layer, and a second electrode disposed on the second semiconductor layer and connected to the second semiconductor layer. The first electrode may be connected to the first semiconductor layer through a via hole formed in the second semiconductor layer and the light emitting layer.

According to another exemplary embodiment of the present disclosure, a light emitting diode element includes a first semiconductor layer, a light emitting layer disposed on the first semiconductor layer, a second semiconductor layer disposed on the light emitting layer, a first electrode connected to the first semiconductor layer, and a second electrode disposed on the second semiconductor layer and connected to the second semiconductor layer. The first electrode may be connected to the first semiconductor layer through a via hole formed in the second semiconductor layer and the light emitting layer.

According to still another exemplary embodiment of the present disclosure, a display apparatus includes a substrate, a first semiconductor layer disposed on the substrate, a light emitting layer disposed on the first semiconductor layer, a second semiconductor layer disposed on the light emitting layer, a first electrode disposed on the second semiconductor layer and connected to the second semiconductor layer, and a second electrode connected to the first semiconductor layer. The upper surface of the second semiconductor layer has an inclined portion. The light emitting layer includes a first light emitting layer overlapping the first electrode, a second light emitting layer positioned near the second electrode, and a third light emitting layer connecting the first light emitting layer and the second light emitting layer. The third light emitting layer may have an inclination corresponding to the inclined portion.

According to exemplary embodiments of the present disclosure, it may be possible to provide a light emitting element (e.g., light emitting diode) and a display apparatus with improved light emission efficiency.

Exemplary embodiments of the present disclosure may provide a light emitting element (e.g., light emitting diode) and a display apparatus capable of implementing high resolution by maximizing the area of the light emitting layer.

According to exemplary embodiments of the present disclosure, it may be possible to provide a light emitting element (e.g., light emitting diode) and a display apparatus with improved luminance uniformity depending on the viewing angle of a display panel.

According to exemplary embodiments of the present disclosure, it may be possible to provide a light emitting element (e.g., light emitting diode) and a display apparatus with low power consumption by improving the efficiency of the light emitting element (e.g., light emitting diode).

### BRIEF DESCRIPTION OF THE DRAWINGS

FIG. 1 is a cross-sectional view illustrating a light emitting element (e.g., light emitting diode) disposed on a substrate according to an exemplary embodiment of the present disclosure.

FIG. 2 is a plan view illustrating a light emitting element (e.g., light emitting diode) according to an exemplary embodiment of the present disclosure.

FIG. 3 is a view illustrating a fabrication process for forming a light emitting element (e.g., light emitting diode) according to an exemplary embodiment of the present disclosure.

FIG. 4 is a view illustrating a fabrication process for forming a light emitting element (e.g., light emitting diode) according to an exemplary embodiment of the present disclosure.

FIG. 5 is a view illustrating a fabrication process for forming a light emitting element (e.g., light emitting diode) according to an exemplary embodiment of the present disclosure.

FIG. 6 is a view illustrating a fabrication process for forming a light emitting element (e.g., light emitting diode) according to an exemplary embodiment of the present disclosure.

FIG. 7 is a view illustrating a fabrication process for forming a light emitting element (e.g., light emitting diode) according to an exemplary embodiment of the present disclosure.

FIG. 8 is a view illustrating a fabrication process for forming a light emitting element (e.g., light emitting diode) according to an exemplary embodiment of the present disclosure.

FIG. 9 is a view illustrating a fabrication process for forming a light emitting element (e.g., light emitting diode) according to an exemplary embodiment of the present disclosure.

FIG. 10 is a view illustrating a fabrication process for forming a light emitting element (e.g., light emitting diode) according to an exemplary embodiment of the present disclosure.

FIG. 11 is a view illustrating the configuration of an electronic device according to an embodiment of the present disclosure.

FIG. 12 is a view schematically illustrating a configuration of a display apparatus according to an exemplary embodiment of the present disclosure.

FIG. 13 is a circuit diagram of a subpixel according to an exemplary embodiment of the present disclosure.

### DETAILED DESCRIPTION

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present disclosure, detailed descriptions of well-known functions and components incorporated herein will be omitted when it is determined that the description may make the subject matter in some embodiments of the present disclosure rather unclear. The terms such as “including”, “having”, “containing”, “comprising”, “constituting”, “consisting of”, “composed of”, “make up of”, and “formed of” used herein are generally intended to allow other components to be added unless the terms are used with the term such as “only”, “merely”, “just” etc. As used herein, singular forms are intended to include plural forms unless the context clearly indicates otherwise.

Terms, such as “first”, “second”, “A”, “B”, “(A)”, or “(B)” may be used herein to describe elements of the present disclosure. Each of these terms is not used to define essence, order, sequence, or number of elements etc., but is used merely to distinguish the corresponding element from other elements.

When it is mentioned that a first element “is connected or coupled to or attached to or adhered to”, “contacts or overlaps” etc. a second element, it should be interpreted that, not only can the first element “be directly connected or coupled to or attached to or adhered to” or “directly contact or overlap” the second element, but a third element can also be “interposed” or “disposed” between the first and second elements, or the first and second elements can “be connected or coupled to or attached to or adhered to”, “contact or overlap”, etc. each other via a fourth element. Here, the second element may be included in at least one of two or more elements that “are connected or coupled to or attached to or adhered to”, “contact or overlap”, etc. each other.

When time relative terms, such as “after,” “following,” “subsequent to,” “next,” “prior to,” “preceding to” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes, lengths, widths, heights, depths, area, volume, etc. are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Various embodiments of the present specification will be described in detail with reference to the accompanying drawings.

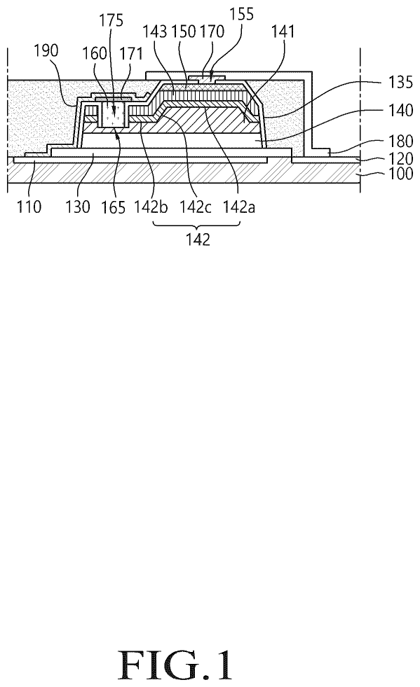

FIG. 1 is a cross-sectional view illustrating a portion of a display apparatus according to an exemplary embodiment of the present disclosure.

Referring to FIG. 1, the display apparatus according to the present exemplary embodiment may include a substrate 100 and a light emitting element (e.g., light emitting diode ED).

A cathode electrode 110 may be disposed on the substrate 100. An anode electrode 120 may be disposed on the substrate 100, spaced apart from the cathode electrode 110.

The substrate 100 may further include a driving element (not shown), and the cathode electrode 110 may be disposed on the driving element and electrically connected to it to supply a low potential signal to the light emitting element (e.g., light emitting diode ED).

An insulating layer 130 may be disposed on the substrate 100.

For example, the insulating layer 130 may be an adhesive layer for adhereing the substrate 100 and the cathode electrode 110 below the insulating layer 130 and the light emitting element above the insulating layer 130.

The light emitting element (e.g., light emitting diode) may be disposed on the insulating layer 130.

The light emitting element (e.g., light emitting diode ED) according to the present embodiment may include a light emitting layer 142, a first electrode 160, and a second electrode 150.

A third semiconductor layer 140 may be disposed on the insulating layer 130.

A first semiconductor layer 141 may be disposed on the third semiconductor layer 140.

The light emitting layer 142 may be disposed on the first semiconductor layer 141.

A second semiconductor layer 143 may be disposed on the light emitting layer 142. The second semiconductor layer 143 may include a p-type semiconductor material.

The first electrode 160 and the second electrode 150 may be disposed with a predetermined spacing therebetween.

The first electrode 160 may be formed on the first semiconductor layer 141 and may be connected thereto.

The first electrode 160 may be connected to the first semiconductor layer 141 through a via hole 175 in the second semiconductor layer 143 and the light emitting layer 142.

The second electrode 150 may be disposed on the second semiconductor layer 143 and may be connected thereto.

The light emitting layer 142 may include a first light emitting layer 142a overlapping the second electrode 150, and a second light emitting layer 142b that is continuous with the first light emitting layer 142a, spaced apart from and adjacent to the first electrode 160, and surrounding a side surface of the first electrode 160.

A distance between the substrate 100 and the first light emitting layer 142a may be greater than a distance between the substrate 100 and the second light emitting layer 142b.

The anode electrode 120 may be disposed on the substrate 100 and between the substrate 100 and the first semiconductor layer 141 to supply a high potential signal.

A first connection electrode 180 may further be included to electrically connect the second electrode 150 and the anode electrode 120.

A first pad 170 may further be included to electrically connect the first connection electrode 180 and the second electrode 150; however, the present disclosure is not limited thereto and the first pad 170 may be omitted.

The second electrode 150, the first pad 170, and the first connection electrode 180 may be transparent.

The cathode electrode 110 may be disposed between the substrate 100 and the first semiconductor layer 141.

A second connection electrode 190 may further be included to electrically connect the cathode electrode 110 and the first electrode 160.

The second connection electrode 190 may be disposed along side surfaces of the first semiconductor layer 141, the light emitting layer 142, and the second semiconductor layer 143. The second connection electrode 190 may further be disposed along a side surface and a part of an upper surface of the insulating layer 130 and a part of an upper surface of the cathode electrode 110.

In the light emitting element (e.g., light emitting diode ED) according to the present embodiment, at least a portion of the light emitting layer 142 may overlap the second connection electrode 190.

A second pad 171 may further be included to electrically connect the second connection electrode 190 and the first electrode 160. However, the present disclosure is not limited thereto, and the second pad 171 may be omitted.

The second connection electrode 190 and the second pad 171 may be transparent. The insulating layer 135 may be transparent.

An insulating layer 135 may further be included and disposed on the second semiconductor layer 143 and the second electrode 150, and may extend along the side surfaces of the second semiconductor layer 143, the light emitting layer 142, the first semiconductor layer 141, and the third semiconductor layer 140.

The insulating layer 135 may include a first opening 155 that overlaps a portion of the second electrode 150 and a second opening 165 that corresponds to the first electrode 160.

The first opening 155 of the insulating layer 135 may expose at least a portion of the second electrode 150, and the second opening 165 of the insulating layer 135 may expose a portion of the first semiconductor layer 141 and at least a portion of the first electrode 160.

The second opening 165 may correspond to the first electrode 160.

The second opening 165 may be included in the via hole 175.

The insulating layer 135 may extend along an inner sidewall of the via hole 175.

A region of the light emitting layer 142 around the via hole 175 may be separated from the first electrode 160 by the insulating layer 135.

The light emitting layer 142 may be in contact with a portion of the insulating layer 135 that extends along the inner sidewall of the via hole 175.

The third semiconductor layer 140 may be disposed between the substrate 100 and the first semiconductor layer 141 and may include, for example, an undoped semiconductor material.

A display apparatus according to an embodiment of the present disclosure may include a light emitting element (e.g., light emitting diode ED) and a driving circuit for driving the light emitting element (e.g., light emitting diode ED). The light emitting element (e.g., light emitting diode ED) may include a first semiconductor layer 141, a light emitting layer 142 disposed on the first semiconductor layer 141, a second semiconductor layer 143 disposed on the light emitting layer 142, a first electrode 160 connected to the first semiconductor layer 141, and a second electrode 150 disposed on the second semiconductor layer 143 and connected thereto. The first electrode 160 may be connected to the first semiconductor layer 141 through a via hole 175 penetrating the second semiconductor layer 143 and the light emitting layer 142.

The light emitting element (e.g., light emitting diode ED) according to an embodiment of the present disclosure may be included in a sub-pixel SP of a display panel.

The light emitting element (e.g., light emitting diode ED) according to an embodiment of the present disclosure may be included in a backlight unit that supplies light to a display panel.

The light emitting element (e.g., light emitting diode ED) according to an embodiment of the present disclosure may be included in a lighting apparatus.

A display apparatus according to an embodiment of the present disclosure may include a substrate 100; a first semiconductor layer 141 disposed on the substrate 100; a light emitting layer 142 disposed on the first semiconductor layer 141; a second semiconductor layer 143 disposed on the light emitting layer 142; a second electrode 150 disposed on the second semiconductor layer 143 and connected thereto; and a first electrode 160 connected to the first semiconductor layer 141. The second semiconductor layer 143 may include a flat portion overlapping the second electrode 150, and another flat portion surrounding the first electrode 160. The second semiconductor layer 143 may further include an inclined portion connecting the flat portion overlapping the second electrode 150 and the flat portion surrounding the first electrode 160. The light emitting layer 142 may include a first light emitting layer 142a having a flat shape and overlapping the second electrode 150, a second light emitting layer 142b having a flat shape and spaced apart from and surrounding the first electrode 160, and a third light emitting layer 142c connecting the first light emitting layer 142a and the second light emitting layer 142b. The third light emitting layer 142c may have an inclination corresponding to the inclined portion of the second semiconductor layer 143.

The display apparatus according to an embodiment of the present disclosure may include the light emitting element (e.g., light emitting diode ED) described in FIG. 1.

A distance between the substrate 100 and the first light emitting layer 142a may be greater than a distance between the substrate 100 and the second light emitting layer 142b.

A portion of the light emitting layer 142 may be disposed below and overlapping the second pad 171.

At least a portion of the light emitting layer 142 may be disposed below the second connection electrode 190.

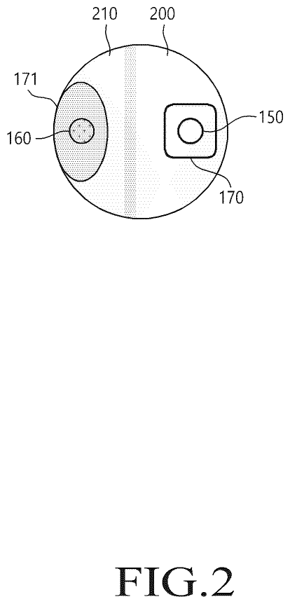

FIG. 2 is a plan view illustrating a light emitting element (e.g., light emitting diode ED) according to an embodiment of the present disclosure.

The light emitting element (e.g., light emitting diode ED) may include a first region 200 and a second region 210.

The light emitting element (e.g., light emitting diode ED) according to an embodiment of the present disclosure may emit light in the first region 200 and the second region 210 excluding the area occupied by the first electrode 160.

The light emitting element (e.g., light emitting diode ED) may emit light in at least a portion of the area of the second pad 171.

A width of the second pad 171 may fully overlap and cover the first electrode 160, and may be greater than a width of the first electrode 160.

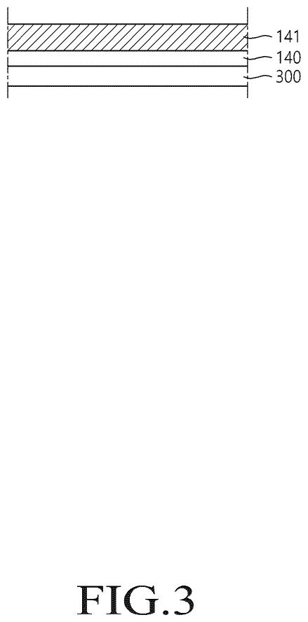

FIG. 3 to FIG. 10 are views illustrating a process flow for manufacturing a light emitting element (e.g., light emitting diode ED) according to an embodiment of the present disclosure.

Referring to FIG. 3, the third semiconductor layer 140 may be deposited on a wafer 300, and the first semiconductor layer 141 may be deposited on the third semiconductor layer 140. For example, the third semiconductor layer 140 may be an undoped semiconductor layer, and the first semiconductor layer 141 may include an n-type semiconductor material.

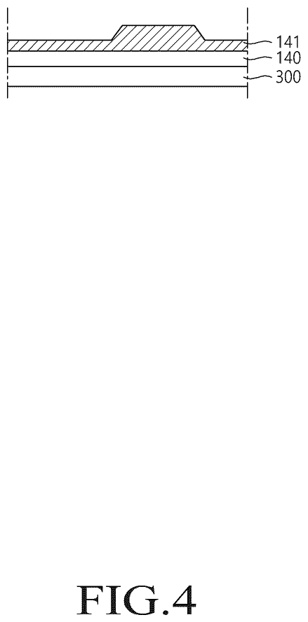

Referring to FIG. 4, an etching process may be performed. In this case, the first semiconductor layer 141 may be etched to form at least two flat layers of different heights and an inclined portion connecting the two layers.

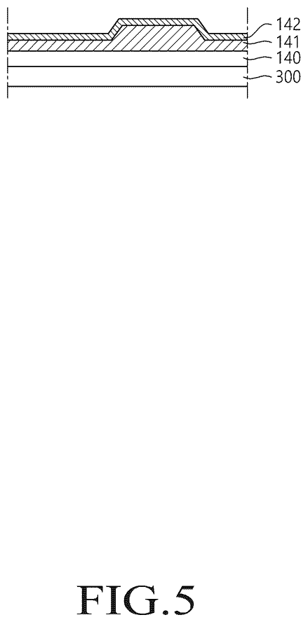

Referring to FIG. 5, the light emitting layer 142 may be formed on an upper surface of the first semiconductor layer 141.

The light emitting layer 142 may be a layer that emits light by the recombination of electrons injected through the first semiconductor layer 141 and holes injected through the second semiconductor layer 143, based on the bandgap difference of the material forming the light emitting layer 142. The light emitting layer 142 may be formed to conform to the shape of two flat portions and an inclined portion connecting the two flat portions in the first semiconductor layer 141 as shown in FIG. 4.

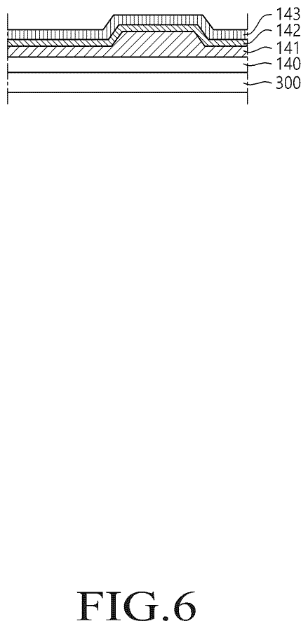

Referring to FIG. 6, the second semiconductor layer 143 may be formed on an upper surface of the light emitting layer 142, and the second semiconductor layer 143 may also be formed to conform to the shape of the light emitting layer 142.

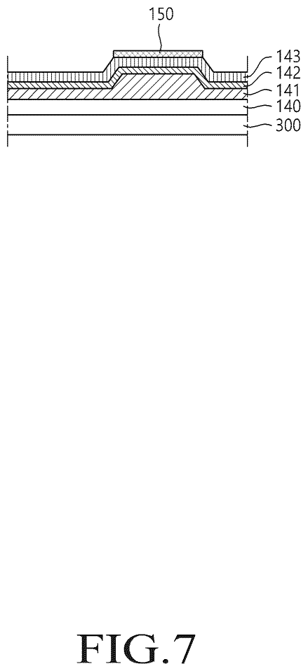

Referring to FIG. 7, the second electrode 150 may be formed on a portion of the higher layer of the second semiconductor layer 143 having two layers.

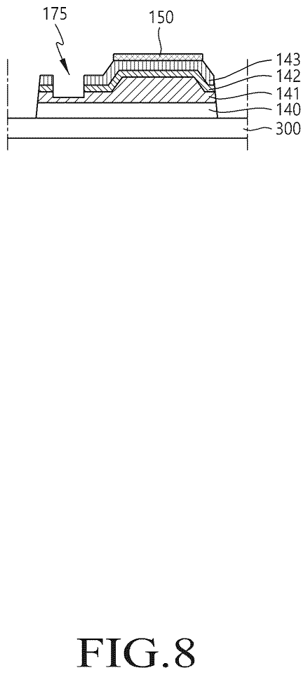

Referring to FIG. 8, a hole (e, g, via hole) 175 may be formed by a photolithography process to penetrate through a portion of the lower-height region of the second semiconductor layer 143 and a portion of the light emitting layer 142 and enter into a portion of the lower-height region of the first semiconductor layer 141 to a depth less than the lower-height, expose side surfaces of the second semiconductor layer 143 and the light emitting layer 142 and a portion of a side surface of the first semiconductor layer 141, and expose a portion of the upper surface of the first semiconductor layer 141 at a height corresponding to depth to which the hole 175 enters into the first semiconductor layer 141. In another exemplary embodiments, a hole 175 may only penetrate through a portion of the lower-height region of the second semiconductor layer 143 and a portion of the light emitting layer 142, and may not enter into the first semiconductor layer 141, in which case, the hole may expose a portion of the upper surface of the lower-height first semiconductor layer 141.

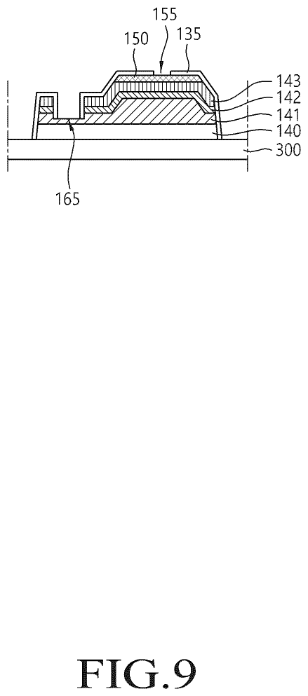

Referring to FIG. 9, the insulating layer 135 may be deposited. The insulating layer 135 may be formed to expose a portion of the upper surface of the second electrode 150 and a portion of the upper surface of the first semiconductor layer 141 exposed through the via hole 175.

The exposed upper surface of the first semiconductor layer 141 may correspond to the via hole 175. The insulating layer 135 may be disposed along an inner sidewall of the via hole 175. The light emitting layer 142 may be in contact with a portion of the insulating layer 135 that extends along the inner sidewall of the via hole 175.

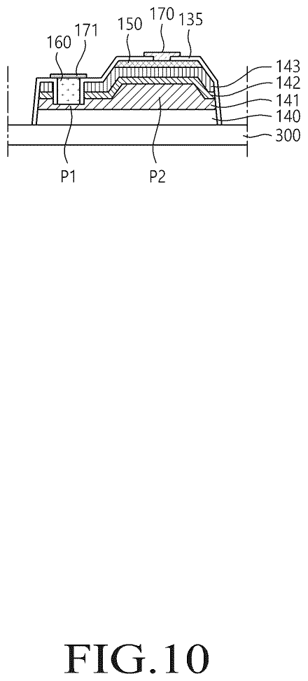

Referring to FIG. 10, the first electrode 160 may be formed to cover the exposed portion of the first semiconductor layer 141 and fill the via hole 175. Subsequently, the first pad 170 may be formed to cover the exposed second electrode 150, and the second pad 171 may be formed to cover the upper surface of the exposed first electrode 160.

The light emitting layer 142 around the via hole 175 may be separated from the first electrode 160 by the insulating layer 135.

The first semiconductor layer 141 may include a first portion P1 overlapping the first electrode 160 and a second portion P2 overlapping the second electrode 150. A thickness of the second portion P2 may be greater than that of the first portion P1.

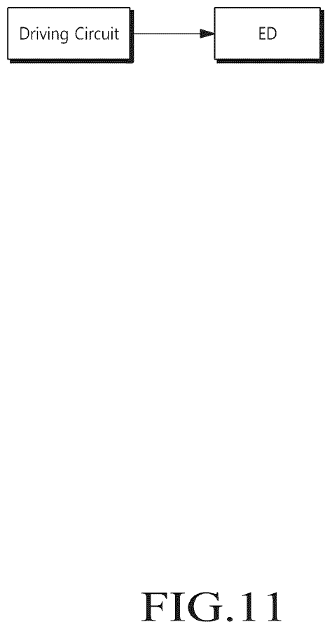

FIG. 11 is a diagram illustrating a configuration of a display apparatus according to an embodiment of the present disclosure.

Referring to FIG. 11, the display apparatus may include a driving circuit and a light emitting element (e.g., light emitting diode ED).

The light emitting element (e.g., light emitting diode ED) according to an embodiment of the present disclosure may be disposed in a sub-pixel SP of a display apparatus 1200 and may emit light according to a driving signal received from the driving circuit.

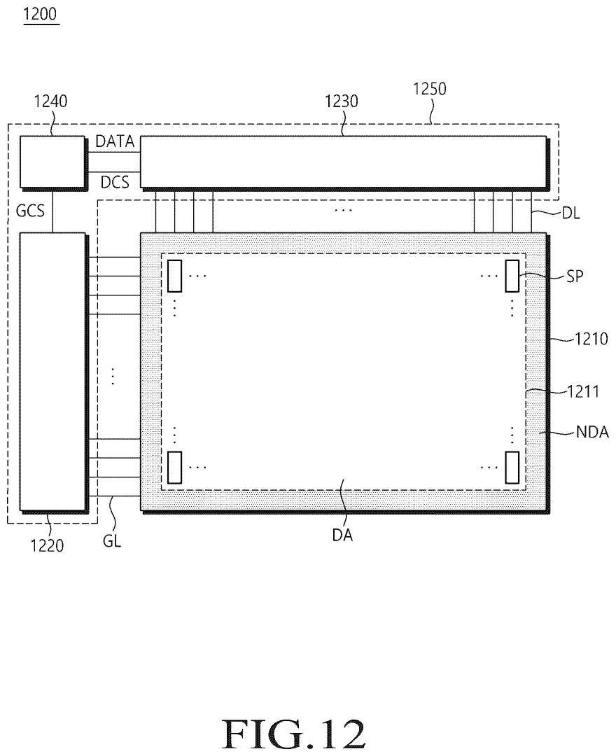

FIG. 12 is a diagram illustrating a schematic configuration of a display apparatus according to an embodiment of the present disclosure.

Referring to FIG. 12, the display apparatus 1200 may include a display panel 1210, a data driving circuit 1230, a gate driving circuit 1220, and a controller 1240.

The display panel 1210 may include a display area DA where an image is displayed and a non-display area NDA where an image is not displayed.

The display panel 1210 may include a substrate 1211, a plurality of sub-pixels SP disposed on the substrate 1211, and various signal lines for driving the sub-pixels SP. The plurality of sub-pixels SP may be disposed in the display area DA.

The various signal lines may include a plurality of data lines DL that transmit data signals (also referred to as data voltages or image signals or video signals) and a plurality of gate lines GL that transmit gate signals (also referred to as scan signals). The plurality of data lines DL and the plurality of gate lines GL may intersect each other.

Each of the plurality of data lines DL may extend in a first direction, and each of the plurality of gate lines GL may extend in a second direction. Here, the first direction may be a column direction, and the second direction may be a row direction, or vice versa. For convenience of explanation, it is assumed below that the data lines DL extend in the column direction and the gate lines GL extend in the row direction.

The data driving circuit 1230 may be a circuit for driving the data lines DL and may output data signals to the data lines DL. The gate driving circuit 1220 may be a circuit for driving the gate lines GL and may output gate signals to the gate lines GL. The controller 1240 may be a device for controlling the data driving circuit 1230 and the gate driving circuit 1220, and may control the driving timing of the data lines DL and the gate lines GL.

The controller 1240 may supply a data driving control signal DCS to the data driving circuit 1230 to control the data driving circuit 1230, and may supply a gate driving control signal GSC to the gate driving circuit 1220 to control the gate driving circuit 1220.

The data driving circuit 1230 may supply data signals DATA to the plurality of data lines DL according to timing control by the controller 1240. The data driving circuit 1230 may receive image data or video signals in digital form from the controller 1240, convert the received image data or video signals into analog data signals, and output them to the plurality of data lines DL.

The gate driving circuit 1220 may supply gate signals to the plurality of gate lines GL according to timing control by the controller 1240. The gate driving circuit 1220 may receive various gate driving control signals (e.g., start signal, reset signal, etc.) along with a first gate voltage corresponding to a turn-on level and a second gate voltage corresponding to a turn-off level, generate gate signals, and supply the generated gate signals to the plurality of gate lines GL.

For example, the data driving circuit 1230 may be connected to the display panel 1210 by a Tape Automated Bonding (TAB) method, or connected to a bonding pad of the display panel 1210 by a Chip On Glass (COG) or Chip On Panel (COP) method, or implemented by a Chip On Film (COF) method and connected to the display panel 1210. Hereinafter, for convenience of explanation, it is assumed that the data driving circuit 1230 is connected to the display panel 1210 by the Chip On Film (COF) method.

The gate driving circuit 1220 may be connected to the display panel 1210 by the Tape Automated Bonding (TAB) method, or connected to a bonding pad of the display panel 1210 by the COG or COP method, or connected to the display panel 1210 by the COF method. Alternatively, the gate driving circuit 1220 may be disposed in a non-active area or an active area of the display panel 1210 in a Gate In Panel (GIP) type.

Meanwhile, at least one of the data driving circuit 1230 and the gate driving circuit 1220 may be disposed in the active area of the display panel 1210. For example, at least one of the data driving circuit 1230 and the gate driving circuit 1220 may be disposed such that it does not overlap with the sub-pixels SP, or all or a part of at least one of the data driving circuit 1230 and the gate driving circuit 1220 may be disposed to overlap with the sub-pixels SP.

The data driving circuit 1230 may be connected to one side (e.g., upper or lower side) of the display panel 1210. Depending on the driving scheme and panel design scheme, the data driving circuit 1230 may be connected to both sides (e.g., upper and lower sides) of the display panel 1210, or to two or more sides among the four sides of the display panel 1210.

The gate driving circuit 1220 may be connected to one side (e.g., left or right side) of the display panel 1210. Depending on the driving scheme and panel design scheme, the gate driving circuit 1220 may be connected to both sides (e.g., left and right sides) of the display panel 1210, or to two or more sides among the four sides of the display panel 1210.

The controller 1240 may be implemented as a component separate from the data driving circuit 1230, or it may be integrated with the data driving circuit 1230 as an integrated circuit. The controller 1240 may be a timing controller commonly used in display technologies, a control device that includes a timing controller and performs additional control functions, a control device other than a timing controller, or a circuit within a control device. The controller 1240 may be implemented using various circuits or electronic components such as an IC (Integrated Circuit), FPGA (Field Programmable Gate Array), ASIC (Application Specific Integrated Circuit), or processor.

The controller 1240 may be mounted on a printed circuit board or a flexible printed circuit, and may be electrically connected to the data driving circuit 1230 and the gate driving circuit 1220 via the printed circuit board or the flexible printed circuit. The controller 1240 may transmit and receive signals to and from the data driving circuit 1230 according to one or more predetermined interfaces. For example, the interface may include an LVDS (Low Voltage Differential Signaling) interface, an EPI interface, or an SPI (Serial Peripheral Interface) interface.

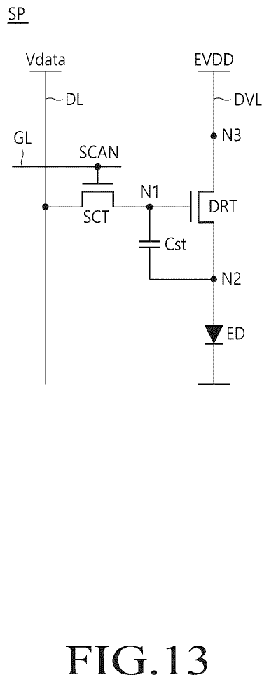

FIG. 13 is a circuit diagram of a sub-pixel according to an embodiment of the present disclosure.

Referring to FIG. 13, a sub-pixel SP disposed in the display panel 110 of the display apparatus 100 according to an embodiment of the present disclosure may include one or more transistors and a capacitor, and may include a light emitting element (e.g., light emitting diode ED). For example, the sub-pixel SP may include a driving transistor DRT, a scan transistor SCT, a storage capacitor Cst, and the light emitting element (e.g., light emitting diode ED).

The driving transistor DRT may be a transistor for driving the light emitting element (e.g., light emitting diode ED) and may include a first node N1, a second node N2, and a third node N3.

The first node N1 of the driving transistor DRT may be a gate node of the driving transistor DRT and may be electrically connected to a source or drain node of the scan transistor SCT. The second node N2 of the driving transistor DRT may be a source or drain node of the driving transistor DRT and may be electrically connected to a pixel electrode of the light emitting element (e.g., light emitting diode ED). The third node N3 of the driving transistor DRT may be electrically connected to a driving voltage line DVL that supplies a driving voltage EVDD.

The scan transistor SCT may be controlled by a scan pulse SCAN, which is a type of gate signal, and may be connected between the first node N1 of the driving transistor DRT and the data line DL. In other words, the scan transistor SCT may be turned on or off according to the scan pulse SCAN supplied from a scan line SCL, which is one type of gate line GL, thereby controlling the connection between the data line DL and the first node N1 of the driving transistor DRT.

The scan transistor SCT may be turned on by the scan pulse SCAN having a turn-on level voltage, and may transmit a data signal Vdata supplied from the data line DL to the first node N1 of the driving transistor DRT.

Here, if the scan transistor SCT is an n-type transistor, the turn-on level voltage of the scan pulse SCAN may be a high level voltage. If the scan transistor SCT is a p-type transistor, the turn-on level voltage of the scan pulse SCAN may be a low level voltage.

The storage capacitor Cst may be connected between the first node N1 and the second node N2 of the driving transistor DRT. The storage capacitor Cst may be charged with an amount of charge corresponding to a voltage difference between both terminals and may maintain the voltage difference for a predetermined frame time. Accordingly, the corresponding sub-pixel SP may emit light during the predetermined frame time.

The light emitting element (e.g., light emitting diode ED) according to an embodiment of the present disclosure may be used as a light source in both edge-type and direct-type backlight units. The light emitting element (e.g., light emitting diode ED) according to an embodiment of the present disclosure may be used in a lighting device.

The embodiments of the present disclosure described above are briefly summarized as follows.

A display apparatus according to embodiments of the present disclosure may include a light emitting element disposed on a substrate. The light emitting element may include a first semiconductor layer disposed on the substrate, a light emitting layer disposed on the first semiconductor layer, a second semiconductor layer disposed on the light emitting layer, a first electrode connected to the first semiconductor layer, and a second electrode disposed on the second semiconductor layer and connected to the second semiconductor layer. The first electrode may be connected to the first semiconductor layer through a via hole of the second semiconductor layer and the light emitting layer.

In the light emitting device according to embodiments of the present disclosure, the light emitting layer may include a first light emitting layer overlapping the second electrode and a second light emitting layer extending from the first light emitting layer and located near the first electrode, and a distance between the substrate and the first light emitting layer may be greater than a distance between the substrate and the second light emitting layer.

The light emitting element according to embodiments of the present disclosure may further include an anode electrode disposed on the substrate and a first connection electrode electrically connecting the second electrode and the anode electrode.

The light emitting element according to embodiments of the present disclosure may further include a first pad electrically connecting the first connection electrode and the second electrode.

The second electrode and the first connection electrode according to embodiments of the present disclosure may be transparent electrodes.

The light emitting element according to embodiments of the present disclosure may further include a cathode electrode disposed between the substrate and the first semiconductor layer and a second connection electrode electrically connecting the cathode electrode and the first electrode. The second connection electrode may be disposed along side surfaces of the first semiconductor layer, the light emitting layer, and the second semiconductor layer.

At least a portion of the light emitting layer in the light emitting element according to embodiments of the present disclosure may overlap the second connection electrode.

The light emitting element according to embodiments of the present disclosure may further include a second pad electrically connecting the second connection electrode and the first electrode.

The second connection electrode of the light emitting element according to embodiments of the present disclosure may be a transparent electrode.

The light emitting element according to embodiments of the present disclosure may further include an insulating layer disposed on the second semiconductor layer and the second electrode and extending along side surfaces of the second semiconductor layer, the light emitting layer, and the first semiconductor layer. The insulating layer may include a first opening overlapping a portion of the second electrode and a second opening overlapping the first electrode. The second opening may correspond to the via hole, and the insulating layer may extend along an inner side surface of the via hole.

In the light emitting element according to embodiments of the present disclosure, the light emitting layer around the via hole may be separated from the first electrode by the insulating layer.

The light emitting layer in the light emitting element according to embodiments of the present disclosure may contact a portion of the insulating layer that extends along an inner side surface of the via hole.

The light emitting element according to embodiments of the present disclosure may further include a third semiconductor layer disposed between the substrate and the first semiconductor layer and comprising an undoped semiconductor material.

The display apparatus according to embodiments of the present disclosure may include a first semiconductor layer, a light emitting layer disposed on the first semiconductor layer, a second semiconductor layer disposed on the light emitting layer, a first electrode connected to the first semiconductor layer, and a second electrode disposed on the second semiconductor layer and connected to the second semiconductor layer. The first electrode may be connected to the first semiconductor layer through a via hole of the second semiconductor layer and the light emitting layer.

According to embodiments of the present disclosure, the light emitting layer may include a first light emitting layer overlapping the second electrode and a second light emitting layer extending from the first light emitting layer and disposed adjacent to the first electrode. The first semiconductor layer may include a first portion overlapping the first electrode and a second portion overlapping the second electrode, and the second portion may have a greater thickness than the first portion.

The light emitting element according to embodiments of the present disclosure may further include an insulating layer disposed on the second semiconductor layer and the second electrode and extending along side surfaces of the second semiconductor layer, the light emitting layer, and the first semiconductor layer. The insulating layer may include a first opening overlapping a portion of the second electrode and a second opening overlapping the first electrode. The second opening may correspond to the via hole, and the insulating layer may extend along an inner side surface of the via hole.

In the light emitting element according to embodiments of the present disclosure, the light emitting layer around the via hole may be separated from the first electrode by the insulating layer.

The display apparatus according to embodiments of the present disclosure may include a substrate, a first semiconductor layer disposed on the substrate, a light emitting layer disposed on the first semiconductor layer, a second semiconductor layer disposed on the light emitting layer, a first electrode disposed on the second semiconductor layer and connected to the second semiconductor layer, and a second electrode connected to the first semiconductor layer. An upper surface of the second semiconductor layer may have a sloped region, and the light emitting layer may include a first light emitting layer overlapping the first electrode, a second light emitting layer adjacent to the second electrode, and a third light emitting layer connecting the first and second light emitting layers. The third light emitting layer may have a slope corresponding to the sloped region of the second semiconductor layer. In the display device according to embodiments of the present disclosure, the light emitting layer may include a first light emitting layer overlapping the second electrode and a second light emitting layer extending from the first light emitting layer and disposed adjacent to the first electrode. A distance between the substrate and the first light emitting layer may be greater than a distance between the substrate and the second light emitting layer.

The display apparatus according to embodiments of the present disclosure may further include an insulating layer disposed on the second semiconductor layer and the second electrode and extending along side surfaces of the second semiconductor layer, the light emitting layer, and the first semiconductor layer. The insulating layer may include a first opening overlapping a portion of the second electrode and a second opening overlapping the first electrode. The second opening may correspond to the via hole, and the insulating layer may extend along an inner side surface of the via hole.

The above description has been presented to enable any person skilled in the art to make and use the technical idea of the present disclosure, and has been provided in the context of a particular application and its requirements. Various modifications, additions, and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display apparatus comprising:
a substrate; and
a light emitting element disposed on the substrate,
wherein the light emitting element comprises:
a first semiconductor layer disposed on the substrate;
a light emitting layer disposed on the first semiconductor layer;
a second semiconductor layer disposed on the light emitting layer;
a first electrode connected to the first semiconductor layer; and
a second electrode disposed on the second semiconductor layer and connected to the second semiconductor layer, and
wherein the first electrode is connected to the first semiconductor layer through a via hole formed in the second semiconductor layer and the light emitting layer.

2. The display apparatus according to claim 1,
wherein the light emitting layer comprises:
a first light emitting layer overlapping with the second electrode; and
a second light emitting layer extending from the first light emitting layer and adjacent to the first electrode,
wherein a distance between the substrate and the first light emitting layer is greater than a distance between the substrate and the second light emitting layer.

3. The display apparatus according to claim 1, further comprising:
an anode electrode disposed on the substrate; and
a first connection electrode electrically connecting the second electrode to the anode electrode.

4. The display apparatus according to claim 3, further comprising a first pad electrically connecting the first connection electrode and the second electrode.

5. The display apparatus according to claim 4, wherein the first pad is a transparent pad.

6. The display apparatus according to claim 3,
wherein the second electrode and the first connection electrode are transparent electrodes.

7. The display apparatus according to claim 1, further comprising:
a cathode electrode disposed between the substrate and the first semiconductor layer; and
a second connection electrode electrically connecting the cathode electrode and the first electrode,
wherein the second connection electrode extends along side surfaces of the first semiconductor layer, the light emitting layer, and the second semiconductor layer.

8. The display apparatus according to claim 6, wherein at least a portion of the light emitting layer overlaps with the second connection electrode.

9. The display apparatus according to claim 6, further comprising a second pad electrically connecting the second connection electrode and the first electrode.

10. The display apparatus according to claim 6, wherein the second connection electrode is a transparent electrode.

11. The display apparatus according to claim 1, further comprising an insulating layer disposed on the second semiconductor layer and the second electrode, the insulating layer extending along side surfaces of the second semiconductor layer, the light emitting layer, and the first semiconductor layer, wherein the insulating layer comprises:
a first opening overlapping with a portion of the second electrode; and
a second opening with overlapping the first electrode,
wherein the second opening corresponds to the via hole, and
wherein the insulating layer extends along an inner side surface of the via hole.

12. The display apparatus according to claim 11, wherein the insulating layer is transparent.

13. The display apparatus according to claim 11, wherein the light emitting layer around the via hole is separated from the first electrode by the insulating layer.

14. The display apparatus according to claim 11, wherein the light emitting layer is in contact with a portion of the insulating layer extending along the inner side surface of the via hole.

15. The display apparatus according to claim 1, further comprising a third semiconductor layer disposed between the substrate and the first semiconductor layer, the third semiconductor layer comprising an undoped semiconductor material.

16. A light emitting element comprising:
a first semiconductor layer;
a light emitting layer disposed on the first semiconductor layer;
a second semiconductor layer disposed on the light emitting layer;
a first electrode connected to the first semiconductor layer; and
a second electrode disposed on the second semiconductor layer and connected to the second semiconductor layer,
wherein the first electrode is connected to the first semiconductor layer through a via hole formed in the second semiconductor layer and the light emitting layer.

17. The light emitting element according to claim 16,
wherein the light emitting layer comprises:
a first light emitting layer overlapping the second electrode; and
a second light emitting layer extending from the first light emitting layer and adjacent to the first electrode,
wherein the first semiconductor layer comprises:
a first portion overlapping the first electrode; and
a second portion overlapping the second electrode, and
wherein the second portion is thicker than the first portion.

18. The light emitting element according to claim 16, further comprising an insulating layer disposed on the second semiconductor layer and the second electrode and extending along side surfaces of the second semiconductor layer, the light emitting layer, and the first semiconductor layer,
wherein the insulating layer comprises:
a first opening overlapping a portion of the second electrode; and
a second opening overlapping the first electrode,
wherein the second opening corresponds to the via hole, and
wherein the insulating layer extends along an inner side surface of the via hole.

19. The light emitting element according to claim 18, wherein the light emitting layer around the via hole is separated from the first electrode by the insulating layer.

20. A display apparatus comprising:
a substrate;
a first semiconductor layer disposed on the substrate;
a light emitting layer disposed on the first semiconductor layer;
a second semiconductor layer disposed on the light emitting layer;
a second electrode disposed on the second semiconductor layer and connected to the second semiconductor layer; and
a first electrode connected to the first semiconductor layer,
wherein an upper surface of the second semiconductor layer includes a sloped portion,
wherein the light emitting layer comprises:
a first light emitting layer overlapping the second electrode;
a second light emitting layer adjacent to the first electrode; and
a third light emitting layer connecting the first light emitting layer and the second light emitting layer, and
wherein the third light emitting layer has an inclination corresponding to the sloped portion.

21. The display apparatus according to claim 20,
wherein the second light emitting layer extends from the first light emitting layer and is adjacent to the first electrode, and wherein a distance between the substrate and the first light emitting layer is greater than a distance between the substrate and the second light emitting layer.

22. The display apparatus according to claim 20, further comprising an insulating layer disposed on the second semiconductor layer and the second electrode, the insulating layer extending along side surfaces of the second semiconductor layer, the light emitting layer, and the first semiconductor layer,
wherein the insulating layer comprises:
a first opening overlapping a portion of the second electrode; and
a second opening overlapping the first electrode,
wherein the second opening corresponds to the via hole, and
wherein the insulating layer extends along an inner side surface of the via hole.
